(19) United States
(12) Patent Application Publication
(10) Pub. No.: US 2013/0069647 A1
(43) Pub. Date: Mar. 21, 2013

(54) TARGETED TRAVELLING WAVE MRI

(71) Applicants: Reiner Umathum, Heidelberg (DE); Stefan Alt, Dossenheim (DE); Marco Mueller, Knittlingen (DE); Michael Bock, Heidelberg (DE)

(72) Inventors: Reiner Umathum, Heidelberg (DE); Stefan Alt, Dossenheim (DE); Marco Mueller, Knittlingen (DE); Michael Bock, Heidelberg (DE)

(21) Appl. No.: 13/603,041

(22) Filed: Sep. 4, 2012

Related U.S. Application Data
(63) Continuation of application No. PCT/EP2011/052958, filed on Mar. 1, 2011.

(30) Foreign Application Priority Data
Mar. 4, 2010 (EP) EP 10155445.9

(51) Int. Cl. G01R 33/48

(52) U.S. Cl. 324/309

(57) ABSTRACT

A travelling wave MRI apparatus is provided that includes a coaxial waveguide arrangement, a cavity for placing therein a subject or object to be imaged, a device for applying a static magnetic field, a device for applying gradient magnetic fields, a device for coupling in electromagnetic excitation pulses having a predetermined operating frequency to induce nuclear magnetic resonance within the subject or object, and a device for detecting an electromagnetic signal resulting from the magnetic resonance. The coaxial waveguide arrangement placed in the cavity of the apparatus comprises a first and a second conductive member arranged in a coaxial arrangement with respect to one another, wherein the first conductive member is formed by a continuous tubular outer member and the second conductive member is formed by a tubular shaped inner member, which is divided in axial direction defining an investigation area.

This nonprovisional application is a continuation of International Application No. PCT/EP2011/052958, which was filed on Mar. 1, 2011, and which claims priority to European Application No. EP 10155445.9, which was filed on Mar. 4, 2010, and which are both herein incorporated by reference.

### BACKGROUND OF THE INVENTION

1. Field of the Invention

The present invention relates to a travelling wave MRI apparatus.

Description of the Background Art

NMR signal detection is traditionally based on Faraday induction in one or multiple radio-frequency resonators. These are brought to close proximity with the sample to be analyzed. Alternative principles involve structured material flux guides, superconducting quantum interference devices, atomic magnetometers, Hall probes or magnetoresistive elements. A common feature of all NMR-implementations until now is that they rely on close coupling between detector and object under investigation. The publication “Travelling-wave nuclear magnetic resonance” of David O. Brunner, Nicola De Zanche, Jürg Frühlich, Jan Paska and Klaas P. Pruessmann, Vol. 457, 19. February 2009, doi:10.1038/nature07752 shows that NMR (nuclear magnetic resonance) can also be excited and detected by long-range interaction, relying on travelling radio frequency (RF) waves, sent and received by an antenna. One benefit of this approach is more uniform coverage of samples that are larger than the wavelength of the MRI signal—an important current issue in MRI of humans at very high magnetic fields. By allowing a significant distance between the probe and the sample, travelling wave interaction also introduces new possibilities in the design of MRI experiments and systems.

Uniform spatial coverage in MRI is traditionally achieved by tailoring the near field of resonant probes. The approach is valid when the RF wavelength at the Larmor frequency is substantially larger than the targeted structure, which does not hold for modern high-field systems. At the highest field strength currently used for human studies, 9.4 T, the Larmor frequency of hydrogen nuclei is 400 MHz, corresponding to a wavelength in tissue in the order of 10 cm. At such short wavelengths, head or body resonators form standing-wave field patterns, which degrade MRI results by causing regional field non-uniformity through interference effects. In the case of transmission, these field inhomogenities induce changes in contrast throughout the image, thus impeding diagnostics.

A travelling wave concept can reduce these interference effects. In addition, travelling radio-frequency waves offer a natural means of exciting and detecting NMR across large distances.

Despite these features, travelling-wave NMR has not been explored so far. In traditional cylindrical imaging devices, the propagation of travelling waves at the NMR frequency is usually not supported by the geometry and the electrical properties of the structures surrounding the sample, such as gradient coils, cryostats, and radio-frequency screens. Their conductive surfaces admit axially travelling waves only beyond a cut-off frequency that is approximately inversely proportional to the bore width. Therefore, travelling-wave NMR requires a high-field magnet that also has a wide bore to bring the cut-off frequency below the NMR frequency, as well as a conductive surface lining the bore.

WO 2009/127431 A1, which corresponds to US 20110115486, is related to a travelling-wave nuclear magnetic resonance method. A method for acquiring an image or spectrum of a subject or object is disclosed, residing within the magnetic field of a magnetic resonance apparatus. First, a predetermined pulse sequence is executed for applying gradient magnetic fields and for coupling in electromagnetic excitation pulses to induce nuclear magnetic resonance within the subject or object. Then an electromagnetic signal resulting from the magnetic resonance is detected and at least one image or magnetic resonance spectrum is constructed of the subject or object from the detected electromagnetic signals. The coupling in of the electromagnetic excitation pulse and/or detecting of the electromagnetic signal is carried out substantially by means of travelling electromagnetic waves. According to WO 2009/127431 A1 the subject or object is located within a cavity of the magnetic resonance apparatus and wherein the travelling electromagnetic waves are axially travelling electromagnetic waves in the cavity, preferably within an elongated tubular structure having an electrically conducting wall. The cavity has a low cut off frequency (i.e. smaller than the operating frequency) when loaded with the subject or object to be imaged and is smaller than the operating frequency.

The publication “Effective delivery of the travelling-wave to distant locations in the body at 7 T”, International Society Mag. Reson. Med. 17, 2009, page 501, relates to the application of the travelling-wave concept to MRI experiments. In MRI experiments excitation and reception are carried out by a single antenna situated at the beginning of a cavity of a 7 T MR-scanner which guides travelling-waves along its longitudinal axis. The radiated travelling-wave first travels through air and then propagates (partly) in a (human) body. A strong damping of the wave occurs during the passage through the body and prohibits excitation of the parts which are located far from the antenna.

According to this publication a new concept is presented to deliver a maximum B1 field strength to the intended region for RF excitation using a waveguide with a coaxial inner conductor. Such waveguide is created by the RF shield of the MR-scanner or an inserted conductive surface, and the inserted cylinder conductive layer which encloses part of the body such as the legs. Due to this inner conductor, the wave initially does not penetrate into the enclosed parts of the body and, thus, the undesirable wave attenuation is avoided.

Nuclear magnetic resonance imaging (MRI) in particular for imaging of selected portions of a patient or another object has so far relied on two main categories of radiofrequency (RF) coils as generally described in U.S. Pat. No. 4,920,318. The first type is a volume resonator dimensioned to be placed around the entire object or patient to be imaged or around a portion thereof. The other type of coil is generally formed by wrapping wire or other conductors on a flat dielectric sheet shaped in such a way as to be positionable close to the portion to be imaged.

There is a strong trend in MRI technology to go to higher static magnetic field strengths. The benefits of these higher magnetic fields are a stronger intrinsic signal due to the stronger magnetisation, increased contrast mechanisms such as BOLD or phase contrast and greater spectral separation for spectroscopic imaging. Since MRI is generally a technique limited by signal-to-noise ratio (SNR), the increase in SNR achievable by increasing the static magnetic field strength enables higher spatial and temporal resolution.

However, an increase in static magnetic field strength requires a proportional increase in operating radio frequency. As a consequence, the wavelength of the RF is shortened correspondingly. For example, the vacuum wavelength of the RF used on a 7 T-system is about 1 m, and it is about 10 cm in human tissue due to the high permittivity of the material.

Moreover, the probe design becomes more intricate because resonator design suffers from reduced robustness due to variable loading in in-vivo applications and because current distributions on the conductive structures of the probe are hardly predictable.

Finally, safety aspects become very intricate due to the strong coupling between sample and probe. RF-induced heating is one of the major concerns, especially at higher frequencies. Slight changes of patient geometry next to the probe conductors may crucially change the situation, worst case scenarios are hard to determine. Safety validation issues thus become a time consuming step in the development of new MRI probes, particularly for transmitting probes.

In order to diminish negative effects of phenomenoms concerning the standing waves in high,magnetic field MRI, two methods have been established so far.

1. Parallel Transmission:

In contrast to conventional MRI methods where the high frequency coils are being excited by only one high frequency transmission unit, a high frequency excitation with the parallel transmission technique is being performed using several local coils and independent transmission units. If the phases and amplitudes of each transmission unit are modulated correctly, inhomogeneities can be minimized and a more uniform deposition of energy can be achieved within the object to be investigated, e.g. the human body.

2. Travelling-Wave:

Concerning the solution disclosed in the abstract of Brunner et al., i.e. “Travelling-wave-method”, a travelling high frequency wave is being coupled into the tomographic device, the geometry of which is shaped such that the travelling-wave is being transmitted within the hollow interior of a cylinder with minimum attenuation. In contrast to using high frequency resonators, this does not result in a pattern of standing waves as long as within the volume to be investigated reflections of the waves are suppressed. As disclosed by Brunner et al., the travelling-wave is coupled into the tomographic device, which serves as a hollow conductive member being filled with ambient air. However, this results in the disadvantage that this concept is only applicable for frequencies above a certain cut-off-frequency. For typically used magnet bore diameter of about 60 cm this limiting frequency is approximately 300 MHz, which also corresponds to the Larmor frequency of protons at 7 T. In particular this prohibits the use of this technology for lower Larmor frequencies, e.g. when using other nuclei (e.g. 23 NA).

### SUMMARY OF THE INVENTION

It is therefore an object of the present invention to provide for coupling in high frequency waves into an object to be investigated particularly in an area of interest without exposing areas of non-interest, i.e. not to be investigated with high frequency waves.

Generally an MRI scanner comprises a device for applying a static, uniform magnetic field in an imaging region where the object to be imaged is located. Such a scanner further comprises a device for applying gradient magnetic fields generating a gradient magnetic field of which magnetic intensity spatially varies in order to encode the spatial coordinates, a device for coupling in electromagnetic excitation pulses having a predetermined operating frequency to induce nuclear magnetic resonance within the subject or object and a device for detecting an electromagnetic signal resulting from the magnetic resonance. In this arrangement the device for applying a static, uniform magnetic field, which can exhibit a coil design with a closed bore or a donut design with an open bore, form a cavity. The remaining systems components such as the device for applying gradient magnetic fields are usually placed within this cavity.

One significant component of MRI is a high frequency coil by means of which a RF field is coupled into the subject or object to be investigated, particularly the human body, to provide for a measurement of the magnetic state, particularly the area of interest which is exposed to the RF field. In contrast to the prior art, such as sketched above, the present invention discloses a particular high frequency device which enables to couple in RF waves targeted into a particular section of interest of the object to be investigated without exposing other areas of the object to RF waves. This offers the advantage that the excluded parts are not unnecessarily exposed to the RF waves and do not contribute to RF exposure limit calculations, which allows for a coupling in of a larger dose of the RF energy at a location where it is required.

In contrast to solutions according to the prior art, the present invention discloses a MRI device having a coaxial arrangement of a first conductive member and a second conductive member, whereas according to the solutions discussed above, tubular elements are being used as conductive members. The MRI device according to the present invention having a first and a second conductive member arranged in a coaxial arrangement with respect to one another comprises a continuous conductive tubular outer member and a tubular shaped inner conductive member, which is divided in axial direction and an investigation area being comprised in this division. According to the present invention the coaxial arrangement is placed within the region of the MRI scanner, where the static uniform magnetic field is present. This is typically the cavity of the MRI scanner, which is formed by the device for applying a static uniform magnetic field.

This division defines the area of investigation of the object to be measured, particularly a human body of a patient to be examined with MRI. The two halves of the inner conductive member enclose the sections of the objects not to be investigated, particularly sparing parts of the human body from the RF field which is only guided through the investigation area, i.e. into the part of the object to be investigated where the RF field is to be coupled in.

The electrical connection of the coaxial arrangement of the MRI device according to the present invention is located at both outer ends. Alternatively, the electrical connection could be established anywhere within the gap between the inner and outer conductive members. Since the RF device according to the present invention is symmetrical, a transmission of the waves to be coupled into the coaxial arrangement according to the present invention, in general is possible in both directions. The coaxial arrangement according to the present invention is used for spectroscopic measurements and is used in terms of magnetic resonance imaging operations. In an advantageous embodiment according to the present invention the area of investigation, i.e. the gap between the two halves of the inner conductive member, is of variable length. Particularly seen in axial direction, the halves of the inner electrical conductive member are arranged moveable in axial direction, so as to allow for variable space, i.e. an investigation area of variable axial length. Still further, seen in radial direction, the annular walls surrounding the object to be investigated, e.g. parts of a human body, are flexible to allow for accommodation of objects of different shape and size, e.g. human beings with a larger waist-size.

The enclosing realized by the halves of the inner conductive member allows for individual investigation areas and allows an adapting of the investigation area as well as an exclusion of those parts of the human body which should not be exposed to the RF field being transmitted by the MRI device according to the present invention having a substantially coaxial arrangement of two conductive members.

Using this coaxial arrangement according to the present invention, the field distribution creating aforementioned inhomogenities are being minimized and a more homogeneous excitation is achieved.

The coaxial arrangement according to the present invention of a MRI device uses the concept of the travelling waves, however limits the disadvantages thereof. Concerning the concept of Brunner et al., as briefly discussed above, always an excitation of the entire object to be investigated, i.e. the entire human body, located within the hollow interior of the tube, is performed. Thus, no specific investigation area is being established, i.e. the entire human body is exposed to the RF field. Still further, a disadvantageous effect lies in the fact that the excitation intensity is dependent on the absorption of the object seen from the entry of the travelling waves in direction of the exit of the travelling waves out of the object to be investigated. According to this solution briefly discussed above, parts of the human body, which are not to be investigated, are unnecessarily exposed to RF fields. Particularly the head or the feet of the patient on the entry side of the travelling-waves to be coupled into the tubular hollow interior are exposed, which is not necessary, if they are not to be examined. By means of the coaxial arrangement of the MRI device according to the present invention, the excitation and the deposition of energy is limited to the area of investigation to which according to the present invention the RF field is directed only. The area of investigation is variable and preferably is chosen such that as shown in the accompanying drawings the target area within the human body is being exposed to the RF field. The length of the area of investigation according to the present invention is variable as well, i.e. the gap between the two halves of the separated inner conductive member is variable, i.e. the members are moved towards one another in axial direction or are moved away with respect to one another in axial direction. The coaxial arrangement comes along with the additional advantage that there is no lower limiting frequency existing due to the geometry of the coaxial arrangement, so that the coaxial arrangement is operable with each frequency concerning MRI. This offers the opportunity to use different nuclei MRI MRS respectively, such as 1H, 23Na, 31P, 13C, 3He, 7Li or 17O, to name but a few, with one and the same device. In the past for each of the different nuclei a variety of different antenna systems, such as RF coils, have been necessary which now can be disposed of. This allows that with one and the same coaxial arrangement according to the present invention, for example MR imaging of a variety of nuclei, offering the advantage in turn, that the patients exposed to MR imaging with different nuclei can stay in their position, consequently are not to be moved from one MR device to another. The images to be taken with the arrangement according to the present invention are coregistered intrinsically.

Still further out of the volume, i.e. the part of the human body to be investigated and disposed to the RF field, no further RF excitation is applicable, so that imaging artefacts are being suppressed. By restricting spin excitation as well as signal reception to the area to be investigated, imaging artefacts and background noise from the excluded parts of the object to be investigated is minimized. Background noise results from noise from not excited sections as well as from excited sections outside of the investigation area.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a principle schematic view of the principle arrangement according to the present invention with an object to be investigated, i.e. the middle portion of a human body;

FIG. 2 shows a perspective view of a human body, the middle portion of which is to be investigated; and

FIG. 3 shows electrical components connected to the MRT device according to the present invention.

### DETAILED DESCRIPTION

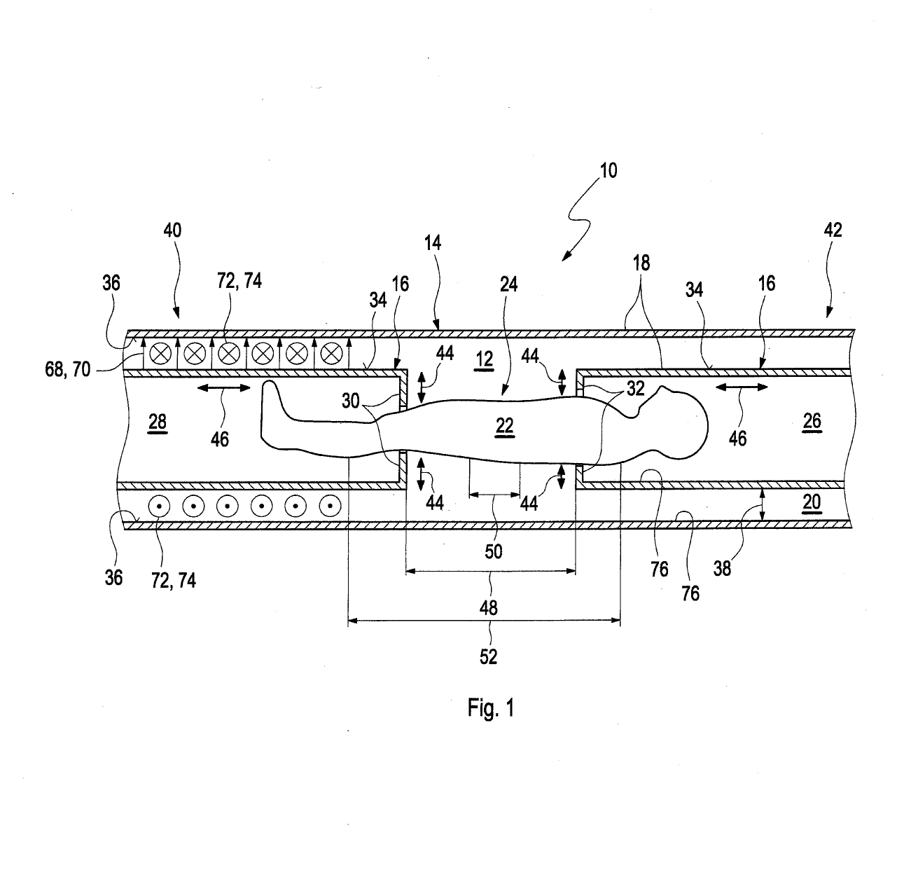

FIG. 1 shows in a schematic view only an MRT device having a coaxial tubular arrangement 18 of a first outer conductive member 14, which extends without any interruption continuously in axial direction. The first outer conductive member 14 surrounds a second inner conductive member 16, which comprises two halves defining an investigation area 24. The two halves of the inner second conductive member 16 are arranged within the hollow interior 12 to be limited by the continuous outer first conductive member 14. As shown in FIG. 1, the first outer conductive member 14 and the second conductive member 16 are spaced apart in radial direction by an annular space labelled reference numeral 38. The width of the annular space between the circumferences of the first conductive member 14 and the second conductive member 16, respectively, can be as small as a few centimetres.

As shown in FIG. 1, the investigation area 24 is defined by the distance between the two adjacent halves of the second inner conductive member 16. In the invention according to FIG. 1, the subject/object 22 to be investigated is a human body, for example the middle portion of which is located in the investigation area 24. The parts of the human body 22, which are not located within the investigation area 24, are excluded from exposition to RF fields by the walls of the second inner conductive member 16 in the first compartment 28 and the second compartment 26.

The travelling-waves being coupled into the coaxial arrangement 18 according to the present invention travel to the annular space 20 having a ring width 38 defined by the outer walls of the first and second compartment 26, 28, respectively, of the second inner conductive member and being limited by the inner wall of the first continuously extending outer conductive member 14. Thus, both portions of the object 22, i.e. in this case the human body, which are located within the compartment 26, 28, respectively, are excluded from exposition to RF fields.

As shown in FIG. 1, the compartment 26, 28, respectively, are being defined by axial conductive surfaces 30, 32, respectively, which are moveable into radial direction as indicated by the double arrows 44. Thus, the axial conductive surfaces 30, 32, respectively, can be adapted in radial direction to different sizes of object 22 to be investigated. Still further, the investigation area 24 substantially defined by the axial positions of the conductive surfaces 30, 32, is variable in axial direction as well as indicated by the double arrows 48, 50, 52, respectively. By axial movement into axial directions of the compartment 26, 28 of the second inner conductive member 16 a first length 50 or a second length 52 of the investigation area 24 seen in axial direction thereof can be performed.

Still further, the varying of the length of the investigation area 24, i.e. in which the middle portion of the human body, i.e. the subject 22, to be investigated is located, allows for a guiding of the RF waves into the region of interest, which can be narrowed to particularly small regions of interest, where a RF field is to be coupled into the subject 22 to be investigated, i.e. into special areas of interest of the human subject 22 as shown in FIG. 1.

The travelling-wave is coupled in at one end of the respective coaxial tubular arrangement 18 and the structure is being excited in the TEM mode, i.e. transversal electromagnetic mode. Both components, i.e. the electrical field E and the magnetic field M, respectively, are oriented perpendicular to one another with respect to the propagation direction. TEM is the native transition mode within a coaxial conductor. The vectors of the electrical field are oriented in radial direction 70 between the circumference of the inner second conductive member 16 and the first continuous conductive member. Perpendicular to the orientation of the electrical field, the vectors of the magnetic field 72 are directed in circular direction 74 within the annular space 20 between the first and second conductive members 14, 16, respectively. Depending of the absolute diameters of the conductors, additional wave propagation of other modes, i.e. TE and TM modes, may be possible beside the TEM mode propagation. The compartments 26, 28 being defined by the axial conductive surfaces 30, 32 and the respective wall sections of the second coaxial conductive surface 34 are substantially free of RF fields. The coupling in of the travelling-wave, i.e. coupling in of the RF field into the object to be investigated occurs in the gap, i.e. the investigation area 24. The transmission of the wave across the interruption is being performed by induced currents and Maxwell currents within the object or subject 22 as well as by means of Maxwell currents only in free space. The object 22 to be investigated is being penetrated by the travelling-wave and the nuclei are being excited. During excitation, travelling waves being transmitted across the investigation area 24 are being guided to the other end of the coaxial arrangement 18 and are being coupled out free of reflections. After excitation the resulting MR-signal, which is being emitted by the excited object 22, is being guided to both ends of coaxial arrangement, of which at least one is equipped with a receiving unit. All components of the coaxial tubular arrangement 18 according to the present invention comprise at least one layer of conductive material, for example copper, to allow for transition of the wave.

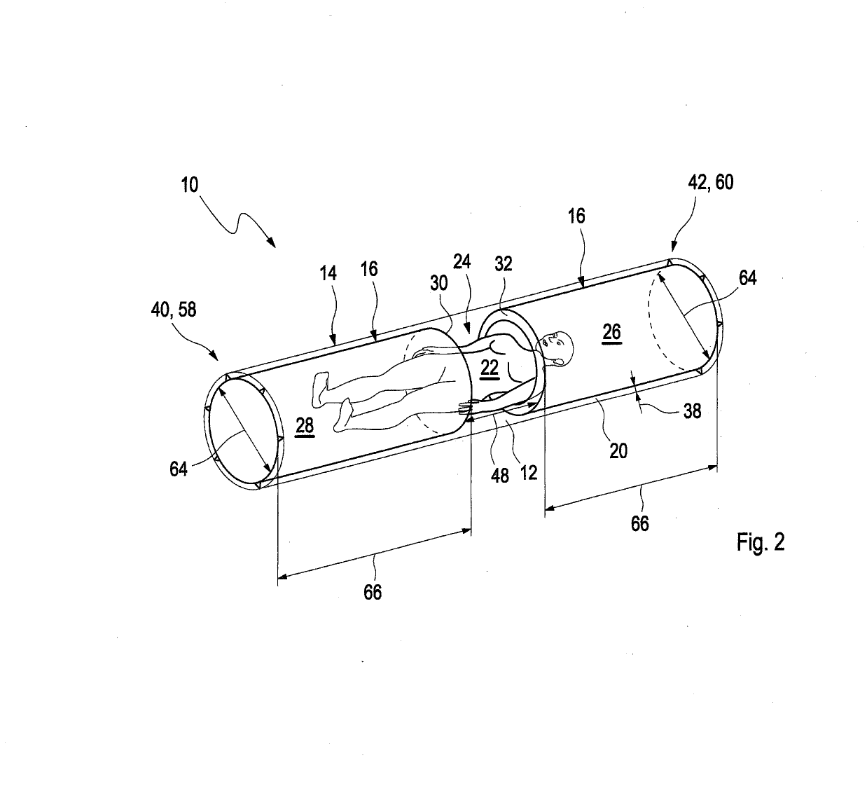

In FIG. 2 a human subject 22 is shown in a perspective view, the legs and feet of the human subject 22 to be investigated, being enclosed in the interior of the first compartment 28, the head of the human subject 22 to be investigated being located in the second compartment 26. The first compartment 28 and the second compartment 26 are arranged adjacent with respect to one another forming between the first axial conductive surface 30 and the second axial conductive surface 32, respectively, the investigation area 24. The inner diameter of the compartments 26, 28, respectively, is labelled with reference numeral 64, the respective compartment length of the compartment 26, 28, respectively, is labelled with reference numeral 66.

The variable length 48 of the investigation area 24 exposing the middle portion of the human subject 22 to be investigated to the RF field is indicated by reference numeral 48. As described previously in connection with FIG. 1, the length 48 between the axial conductive surface 30, 32 of the compartment 26, 28, respectively, can be varied in axial direction to create a larger or smaller middle portion, which is exposed to the RF field. The coaxial arrangement 18 according to the perspective view in FIG. 2 comprises a first end portion 40 and a second end portion 42, respectively. The first end portion 40 may include an insertion end 58, where the travelling-wave, i.e. the RF field, is to be coupled in to the coaxial arrangement 18 according to the present invention. The second end portion 42 according to the perspective view in FIG. 2 comprises a dissipating end 60, where the travelling-waves are leaving the coaxial arrangement 18. Reference numeral 38 indicates the ring width of the annular space 20 between an inner wall of the first outer conductive member 14 and the outer circumference of the second inner conductive member 16 limiting the compartments 26, 28.

The Larmor frequency of protons is about 300 MHz at a magnetic field strength of about 7 T. The wavelength in air is 1 m at a frequency of 300 MHz. The wavelength is dependent on the medium in which the wave is propagating. In human tissue the wavelength is about 15 cm at a frequency of 300 MHz.

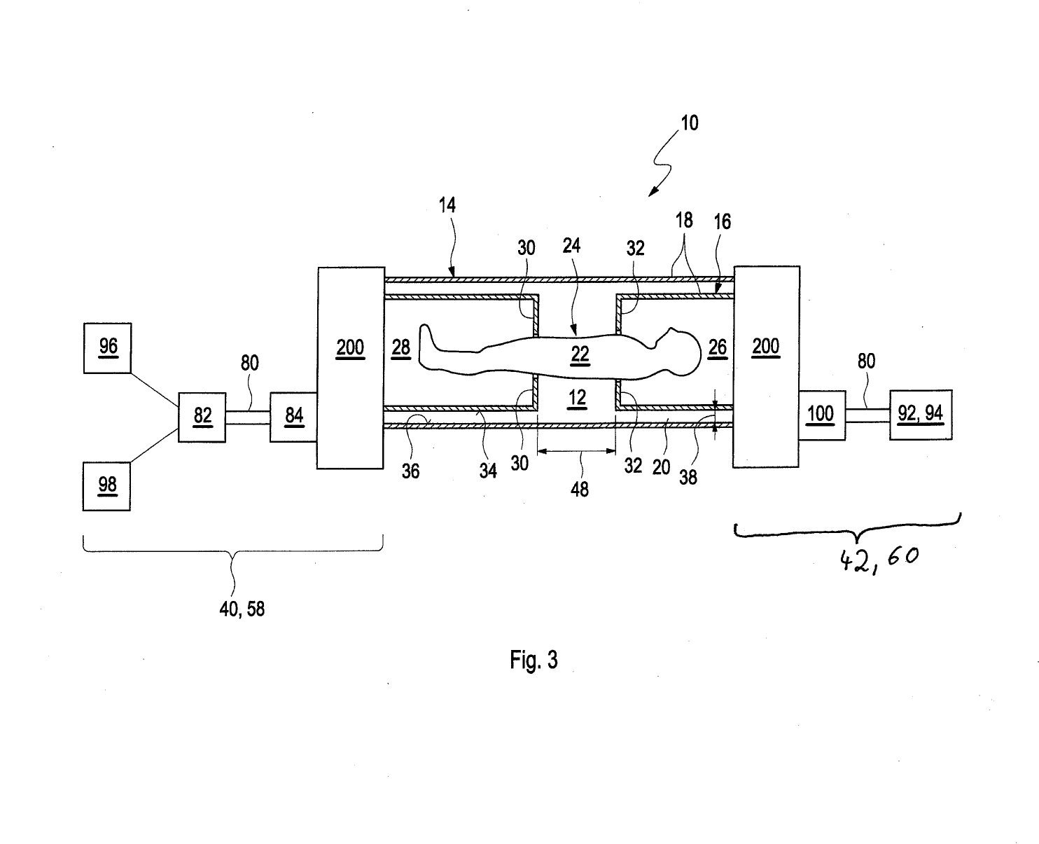

FIG. 3 shows an embodiment of the present invention according to which by means of a coaxial cable 80 travelling waves are sent and directed via a transmit/receive switch. By means of the transmit/receive switch 82 a bi-directional operating mode is achieved. After a first impedance matching network 84 the first transition section 200 is located. This electrical/mechanical transition can be realized in various ways, e.g. by one or more coaxial cables or by a double funnel shaped structure, which continuously extends its diameters from those of a coaxial cable to those of the coaxial arrangement 18.

The input of the RF-field to the coaxial tubular arrangement 18 can be realised by direct inductively, capacitively or galvanically coupling to the supply chain including e.g. a transmit/receive switch 82, a first impedance matching network 84 and a first transition section 86 to the conductive members 14, 16.

At the second end portion 42, i.e. the dissipating end 60, the travelling wave is dissipated, i.e. coupled out free of reflections via a second impedance matching device 100 and a section of a coaxial cable 80 to an energy dissipating device 92 or a second receiver 94.

The middle portion of the human subject 22 is exposed to the RF field within the investigation area 24. The investigation area 24 has a variable length 48 according to the dotted double arrow, which is variable between a first length 50 shorter than the variable length 48 as indicated in FIG. 1, and for example a second length 52 exceeding the variable length 48 as shown in FIG. 1. As already described in connection with FIG. 1, the second inner conductive member 16, which defines the investigation area 24, comprises a first compartment 28 and a second compartment 26. The compartments 26, 28 enclose the head, part of the legs and the feet of the human subject 22, that are not to be exposed to the RF field. The travelling waves entering the coaxial arrangement 18 at the first end portion 40, i.e. the insertion end 58, propagates through the annular space 20 established between the parallel extending conductive members 14, 16, respectively, in axial direction.

As can be derived from FIG. 3 by means of the transmit/receive switch 82 either a transmitter 96 generates waves to be coupled in into the coaxial cable 80 or in the alternative a receiver unit 98 is active and obtains signals through the coaxial cable 80. As shown in FIG. 3, a first impedance matching network 84 is arranged behind the transmit/receive switch 82. At the other end of the coaxial tubular arrangement 18 according to the present invention, another transition section 200 as well as another impedance matching network 100 connects the coaxial arrangement to a second reflection-free receiver 94 or another energy dissipating device 92.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An apparatus for magnetic resonance imaging, the apparatus comprising:
a cavity for placing therein a subject or object to be imaged;
a device for applying a static magnetic field;
a device for applying gradient magnetic fields;
a device for coupling in electromagnetic excitation pulses having a predetermined operating frequency to induce nuclear magnetic resonance within the subject or object; and
a device for detecting an electromagnetic signal resulting from the magnetic resonance,
wherein the cavity comprises a first and a second conductive member arranged in a coaxial arrangement with respect to one another, and
wherein the first conductive member is formed by a continuous tubular outer member and the second conductive member is formed by a tubular shaped inner member, which is divided in an axial direction defining an investigation area.

2. The apparatus according to claim 1, wherein the first conductive member and the second conductive member are separated from one another by an annular space.

3. The apparatus according to claim 1, wherein the electromagnetic excitation pulses are coupled into the investigation area by at least one travelling-wave.

4. The apparatus according to claim 2, wherein the annular space and the investigation area are filled with air or a dielectric medium, partially or entirely.

5. The apparatus according to claim 1, wherein the first conductive member extends continuously from a first end portion to a second end portion.

6. The apparatus according to claim 1, wherein the first conductive member and the second conductive member of the coaxial tubular arrangement each comprises at least one conductive layer.

7. The apparatus according to claim 1, wherein the investigation area is defined by a gap between adjacent compartments of the first conductive member.

8. The apparatus according to claim 1, wherein the investigation area has a variable length with respect to an axial direction.

9. The apparatus according to claim 7, wherein each of the compartments comprises conductive surfaces defining openings for the object or subject to be investigated.

10. The apparatus according to claim 9, wherein the openings in the conductive surfaces are variable in width with respect to a radial direction.

11. The apparatus according to claim 1, wherein the coaxial arrangement includes end portions comprising transition sections.

12. The apparatus according to claim 1, wherein the coaxial arrangement comprises a transmit/receive switch at at least one of the end portions.

13. The apparatus according to claim 1, wherein the coaxial arrangement comprises a dissipating end including either a reflection-free material, an absorbing material, or a receiver or another energy dissipating device.

14. The apparatus according to claim 1, wherein the coaxial arrangement comprises at least one wave generating device at at least one of the end portions.

15. The apparatus according to claim 1, wherein the coaxial arrangement comprises at least one receiving unit assigned to a transmit/receive switch via an impedance matching network, respectively.

16. The apparatus according to claim 1, wherein the coaxial tubular arrangement is configured to be operable with one or more frequencies in a simultaneous or subsequent mode.

17. A method for magnetic resonance imaging using the apparatus according to claim 1 with a coaxial arrangement comprising a first conductive member and a second conductive member defining an investigation area, the method comprising:
coupling in travelling-waves at a first end portion of the coaxial arrangement;
guiding the travelling-waves to an investigation area; and
receiving the travelling-waves at a reflection-free termination or a second receiver assigned to a second end portion of the coaxial arrangement.

18. The method according to claim 17, wherein the travelling-waves are coupled in at an insertion end of the coaxial arrangement and propagate through an annular space between the first conductive member and the second conductive member to an opposite end and vice-versa.

19. The method according to claim 17, wherein portions or sections of the subject or object to be investigated are shielded against exposure to the travelling waves by at least one compartment of the second conductive member.

20. The method according to claim 17, wherein the investigation area is variable with respect to its length.

21. The method according to claim 17, wherein the coaxial arrangement is supplied by at least one wave generating device at a first end portion.

22. The method according to claim 17, wherein the coaxial tubular arrangement is configured to be operated with one or more frequencies in a simultaneous or subsequent mode.

23. The method according to claim 17, wherein magnetic resonance imaging is performed using any MR responsive nuclei, e.g. 1H, 23Na, 31B, 13C, 3He, 7Li and 17O.
